(19) United States
(12) Patent Application Publication
(10) Pub. No.: US 2010/0263588 A1
(43) Pub. Date: Oct. 21, 2010

(54) METHODS AND APPARATUS FOR EPITAXIAL GROWTH OF SEMICONDUCTOR MATERIALS

(76) Inventor: Gan Zhiyin, Pudong District (CN)

Correspondence Address: DICKE, BILLIG & CZAJA, FIFTH STREET TOWERS, 100 SOUTH FIFTH STREET, SUITE 2250, MINNEAPOLIS, MN, 55402, US

(21) Appl. No.: 12/423,910

(22) Filed: Apr. 15, 2009

(51) Int. Cl. C30B 25/10; C23C 16/22; C30B 25/02

(52) U.S. Cl. 117/98; 118/715; 118/722; 118/725; 117/88; 117/104; 118/724; 118/728

(57) ABSTRACT

Epitaxial growth of semiconductor materials is carried out by introducing two or more reaction gases along with their carrier gas into a reaction chamber via one or more concentric pipe inlets and a plurality of separately distributed injection ports with a gas distribution system. The reaction gas can be injected into the reaction chamber either continuously or in pulse mode, wherein reaction gases are mixed together or injected alternately into the reaction chamber. The semiconductor materials are deposited on the substrates which are located on the rotating heated susceptor within the reaction chamber.

### FIELD OF THE INVENTION

The invention relates generally to semiconductors. More particularly, the invention relates to epitaxial growth of semiconductor materials.

### BACKGROUND OF THE INVENTION

The present invention relates to epitaxial growth and more particularly, but not exclusively, is concerned with metal organic chemical vapor deposition (MOCVD) and atomic layer deposition (ALD).

It is known that the CVD processes, if properly controlled, produce thin films having organized crystal lattice. Especially important are the thin films having the same crystal lattice structures as the underlying substrates. The layers by which such thin films grow are called the epitaxial layers. MOCVD is considered as an important technique to achieve epitaxial growth of semiconductor and high temperature compounds such as GaAs, InP, GaN, AlGaAs, and InGaAsP. The epitaxial layers are typically grown by causing appropriate reactant chemicals in gaseous form to flow over the wafers in controlled quantities and at controlled rates, while the wafers are heated and usually rotated.

MOCVD reactors have various geometric configurations, including horizontal reactors in which wafers are mounted at an angle to the inflowing reactant gases and a horizontal tube is provided having an inlet zone at one end wherein the gaseous precursors are mixed. The reaction chamber contains a heated horizontally disposed substrate so that the mixed precursors and a carrier gas from the inlet zone can flow over the substrate where the chemical vapor deposition reaction takes place. In another arrangement, the reactor includes a vertical tube in which the reactant gases are injected downwardly onto the center of the susceptor from the inlet zone at the top, then flow radially along the surface of the susceptor. It is known to provide multiple wafer designs wherein the substrate may be rotated to improve uniformity of thickness and composition of the deposited layer.

The core part of MOCVD equipment is the reactor, which determines the performance of the epitaxial growth. Many conventional reactors have the problem of pre-reaction and ceiling-coating, which can result in wasting of the precursors and contamination of the reactor.

### SUMMARY OF THE INVENTION

One embodiment provides a reactor for epitaxial growth of semiconductor materials. The reactor includes a reaction chamber for accommodating a heated substrate upon which a semiconductor material is to be deposited by reaction of gaseous precursors. The reactor includes three concentric central conduits configured to vertically inject a first precursor, a second precursor, and a third precursor into the reaction chamber and to radially flow the first precursor, the second precursor, and the third precursor upon the heated substrate. The reactor includes a first chamber for a fourth precursor. The first chamber includes a baffle plate therein. The reactor includes a plurality of conduits connecting the first chamber to the reaction chamber. The plurality of conduits are configured to provide distributed spray paths along which the fourth precursor is passed to the reaction chamber.

In one embodiment, the reactor includes a cooling chamber configured to cool the plurality of conduits and connected solid structures. In one embodiment, the reactor includes a cooling chamber configured to cool walls of the reaction chamber. In one embodiment, the three concentric central conduits are configured to continuously inject the first precursor, the second precursor, and the third precursor, and the plurality of conduits for distributed spray paths are configured to continuously inject the fourth precursor for metal organic chemical vapor deposition. In another embodiment, the three concentric central conduits and the plurality of conduits for distributed spray paths are configured to inject the first precursor, the second precursor, the third precursor, and the fourth precursor in a pulse mode where a duty cycle of the pulses is adjustable. In one embodiment, the three concentric central conduits and the plurality of conduits for distributed spray paths are configured to alternately inject the first precursor, the second precursor, the third precursor, and the fourth precursor for atomic layer deposition. In one embodiment, the reactor includes a susceptor within the reaction chamber. The susceptor is configured to support the substrate. In one embodiment, the reactor includes a heater within the reaction chamber. The heater is configured to heat the susceptor. In one embodiment, the susceptor is configured to rotate. In one embodiment, the susceptor is configured to support an additional substrate.

Another embodiment provides a method for epitaxial growth of semiconductor materials from multiple gaseous precursors. The method includes heating a substrate upon which a semiconductor material is to be deposited by reaction of the gaseous precursors in a reaction chamber. The method includes injecting a first precursor, a second precursor, and a third precursor into the reaction chamber to radially flow the first precursor, the second precursor, and the third precursor upon the heated substrate. The method includes injecting a fourth precursor into the reaction chamber through a plurality of conduits connected to the reaction chamber, the plurality of conduits providing distributed spray paths along which the fourth precursor is passed to the reaction chamber.

In one embodiment, the method includes cooling the plurality of conduits and connected solid structures. In one embodiment, the method includes cooling walls of the reaction chamber. In one embodiment, injecting the first precursor, the second precursor, the third precursor, and the fourth precursor includes continuously injecting the first precursor, the second precursor, the third precursor, and the fourth precursor to perform metal organic chemical vapor deposition. In another embodiment, injecting the first precursor, the second precursor, the third precursor, and the fourth precursor includes injecting the first precursor, the second precursor, the third precursor, and the fourth precursor in a pulse mode where a duty cycle of the pulses is adjustable. In one embodiment, injecting the first precursor, the second precursor, the third precursor, and the fourth precursor includes alternately injecting the first precursor, the second precursor, the third precursor, and the fourth precursor to perform atomic layer deposition. In one embodiment, heating the substrate includes heating a susceptor upon which the substrate is placed. In one embodiment, the method includes rotating the substrate within the reaction chamber. In one embodiment, the method includes heating an additional substrate upon which the semiconductor material is to be deposited by reaction of the gaseous precursors in the reaction chamber.

Another embodiment provides a reactor. The reactor includes a reaction chamber configured to accommodate a substrate and at least one concentric central conduit configured for injecting a first precursor into the reaction chamber. The reactor includes a gas distribution chamber for a second precursor and a plurality of conduits connecting the gas distribution chamber to the reaction chamber to provide a plurality of distributed spray paths along which the second precursor is passed to the reaction chamber.

### BRIEF DESCRIPTION OF THE DRAWINGS

The accompanying drawings are included to provide a further understanding of embodiments and are incorporated in and constitute a part of this specification. The drawings illustrate embodiments and together with the description serve to explain principles of embodiments. Other embodiments and many of the intended advantages of embodiments will be readily appreciated as they become better understood by reference to the following detailed description. The elements of the drawings are not necessarily to scale relative to each other. Like reference numerals designate corresponding similar parts.

FIG. 1 is a plan view of a reactor in accordance with an embodiment of the present invention.

FIG. 2 is a section through the reactor of FIG. 1 along the line A-A.

FIG. 3 is a section through the reactor of FIG. 1 along the line B-B.

FIG. 4 is an underneath view of the reactor of FIG. 1 in the direction indicated by arrow C.

### DETAILED DESCRIPTION OF THE PREFERRED EMBODIMENTS

The present invention overcomes and/or minimizes the problems discussed above by separately introducing the gaseous precursors into the reaction chamber and combining the advantages of radial flow of vertical injection reactors and traditional showerhead structure, which emits the reactants to the heated substrate on the susceptor through thousands of vertical nozzles.

According to a first aspect of the present invention, an apparatus for growing epitaxial layers on one or more wafers by chemical vapor deposition is provided, which reactor comprises:

(1) a reaction chamber for accommodating a heated substrate upon which said material is to be deposited by reaction of said precursors,

(2) three concentric central conduits connecting the reaction chamber for the first, second and third precursors,

(3) a first chamber for the fourth precursor has a baffle plate inside,

(4) hundreds of conduits connecting the first chamber to the reaction chamber to provide distributed spray flow paths along which the fourth precursor can pass to the reaction chamber, and

(5) a means for cooling the said conduits and its connected metal solid structures.

According to a second aspect of the present invention there is provided a method of producing an epitaxial layer by reaction of first, second, third and fourth gaseous precursors by chemical vapor deposition which method comprises cooled precursors separately injected by vertical flow along a plurality of distributed paths, and radial flow through concentric conduits, into a reaction chamber containing a heated substrate upon which an epitaxial layer is to be deposited by the reaction of the said precursors occurs.

One or all of the said precursors may be in the form of a single precursor or in the form of a mixture of substances which is chemically stable.

If desired, the reaction chamber may be such as to accommodate more than one substrate.

By balancing the vertical injected radial flow and distributed spray flow of the reactant gases, the invention can easily reach to optimal flows required for chemical vapor deposition of preferably uniform or uniformly conformed thin films and multi-layer films of desired composition and can remarkably minimize the problem of ceiling-coating.

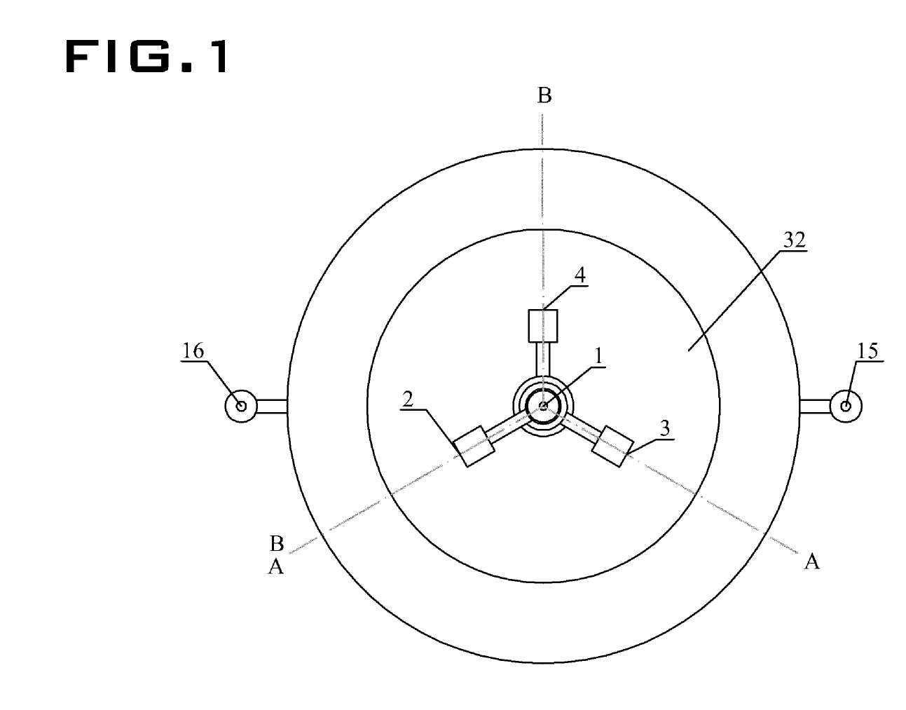

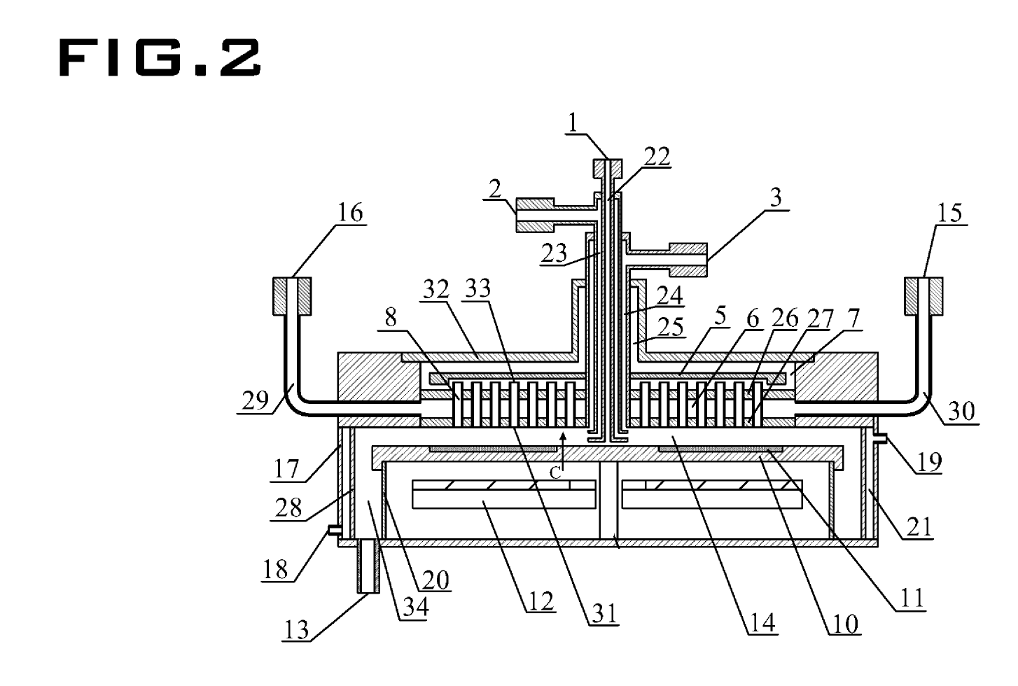

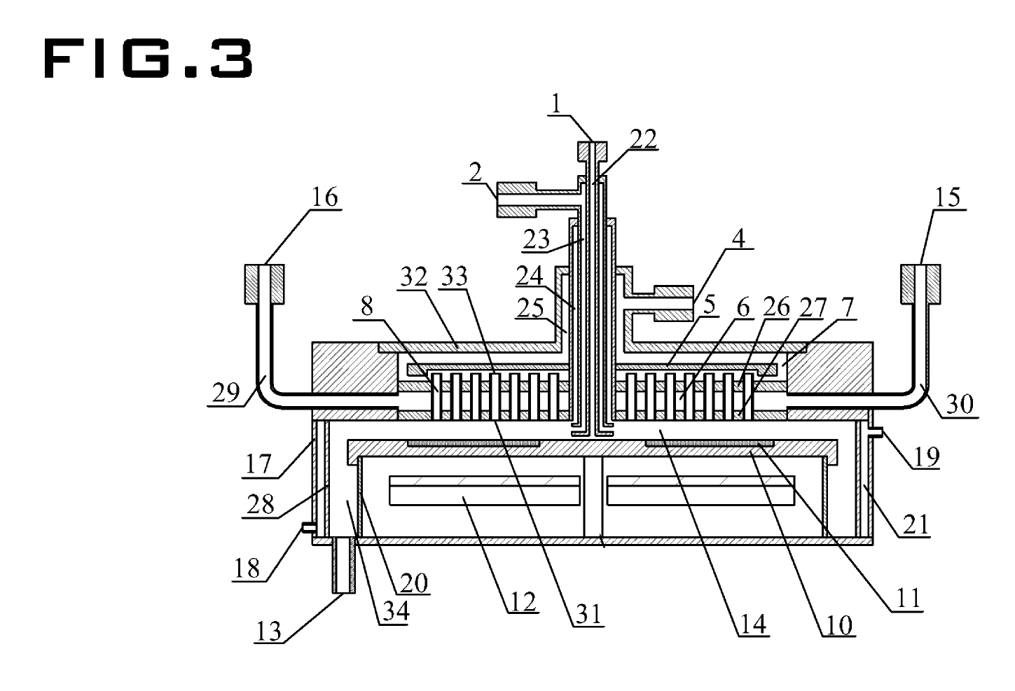

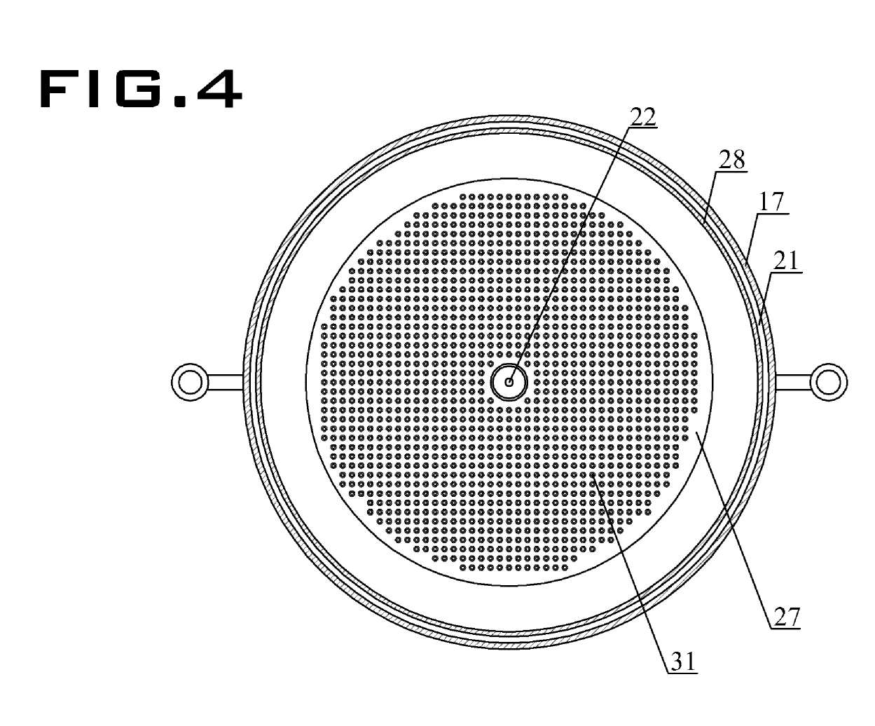

According to FIGS. 1 to 4, the reactor comprises four inlets 1, 2, 3 and 4 which are in communication with concentric central galleries 22, 23, 24 and 25 respectively. The inlet 1 is for a first precursor (e.g. ammonia) and carrier gas. The inlet 2 is for a second precursor (e.g. trimethyl gallium) and carrier gas. The inlet 3 is for a third precursor (e.g. ammonia) and carrier gas. The inlet 4 is for a fourth precursor (e.g. trimethyl gallium) and carrier gas.

The first plate 26 defines, with the top closure plate 32, a first chamber 7 which has a baffle plate 5 inside. The baffle plate 5 can improve the velocity uniformity of the gas to be introduced into the reaction chamber 14 located between the second plate 27 and the horizontal surface of the susceptor 10. The second plate 27 forms, with the first plate 26, a cooling chamber 6.

A plurality of conduits 8 is provided between the first chamber 7 and the reaction chamber 14. They have inlets 33 located in the first chamber 7 and pass through the cooling chamber 6 without communicating therein. They are bonded to the plates 26 and 27 by, for example, vacuum brazing. The conduits terminate in outlets 31 in the form of injector nozzles in the reaction chamber 14 and provide a plurality of distributed flow paths from the first chamber 7 to the reaction chamber 14.

The coolant inlet 16 is in communication with a gallery 29 which in turn communicates with the cooling chamber 6. The coolant outlet 15 is similarly linked by gallery 30 to the cooling chamber 6. The coolant (e.g. water) passing through the cooling chamber 6 contacts the outer surfaces of the conduits 8 passing through the cooling chamber 6 and thereby cools the gases passing through the conduits 8, its connected solid structures and the upper surface of the second plate 27.

The reactor comprises a vertical tube having cylindrical walls 17 and 28. A susceptor 10 is mounted on a susceptor support 20 typically formed of quartz. The susceptor support 20 may include a means (not shown) of giving a spin to the susceptor 10 about the longitudinal axis of the reactor so that the substrates 11 are rotated during the MOCVD process. In this way, the quality and uniformity of the thin film deposited on the substrate 11 can be improved.

The substrate 11 (in the form of one or more wafers) is placed upon the susceptor 10 so that it can be heated by contact with the susceptor to a temperature above that at which the precursors decompose and react. The heater 12 is under the susceptor 10. The heating of the susceptor may be by, for example, induction heating, radiation heating or resistance heating as desired.

The cylindrical walls 17 and 28 form a side cooling chamber 21 which has a coolant inlet 18 and outlet 19. The coolant passing through the side cooling chamber 21 contacts the inner surface of wall 17 and the outer surface of wall 28 so as to cool the exhaust gases passing through the exhaust conduit 34 formed by walls 28 and 20 and to keep the outer surface of wall 17 at a normal temperature. An exhaust port 13 is provided in communication with the exhaust conduit 34. The exhaust port 13 is generally connected to a low pressure exhaust system (e.g. vacuum pump).

In the preceding Detailed Description, reference is made to the accompanying drawings, which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments can be positioned in a number of different orientations, the directional terminology is used for purposes of illustration and is in no way limiting. It is to be understood that other embodiments may be utilized and structural or logical changes may be made without departing from the scope of the present invention. The preceding detailed description, therefore, is not to be taken in a limiting sense, and the scope of the present invention is defined by the appended claims.

It is contemplated that features disclosed in this application can be mixed and matched to suit particular circumstances. Various other modifications and changes will be apparent to those of ordinary skill.

1. A reactor for epitaxial growth of semiconductor materials, the reactor comprising:
a reaction chamber for accommodating a heated substrate upon which a semiconductor material is to be deposited by reaction of gaseous precursors;
three concentric central conduits configured to vertically inject a first precursor, a second precursor, and a third precursor into the reaction chamber and to radially flow the first precursor, the second precursor, and the third precursor upon the heated substrate;
a first chamber for a fourth precursor, the first chamber comprising a baffle plate therein; and
a plurality of conduits connecting the first chamber to the reaction chamber, the plurality of conduits configured to provide distributed spray paths along which the fourth precursor is passed to the reaction chamber.

2. The reactor of claim 1, further comprising:
a cooling chamber configured to cool the plurality of conduits and connected solid structures.

3. The reactor of claim 1, further comprising:
a cooling chamber configured to cool walls of the reaction chamber.

4. The reactor of claim 1, wherein the three concentric central conduits are configured to continuously inject the first precursor, the second precursor, and the third precursor, and the plurality of conduits for distributed spray paths are configured to continuously inject the fourth precursor for metal organic chemical vapor deposition.

5. The reactor of claim 1, wherein the three concentric central conduits and the plurality of conduits for distributed spray paths are configured to inject the first precursor, the second precursor, the third precursor, and the fourth precursor in a pulse mode, a duty cycle of the pulses being adjustable.

6. The reactor of claim 5, wherein the three concentric central conduits and the plurality of conduits for distributed spray paths are configured to alternately inject the first precursor, the second precursor, the third precursor, and the fourth precursor for atomic layer deposition.

7. The reactor of claim 1, further comprising:
a susceptor within the reaction chamber, the susceptor configured to support the substrate.

8. The reactor of claim 7, further comprising:
a heater within the reaction chamber, the heater configured to heat the susceptor.

9. The reactor of claim 7, wherein the susceptor is configured to rotate.

10. The reactor of claim 7, wherein the susceptor is configured to support an additional substrate.

11. A method for epitaxial growth of semiconductor materials from multiple gaseous precursors, the method comprising:
heating a substrate upon which a semiconductor material is to be deposited by reaction of the gaseous precursors in a reaction chamber;
injecting a first precursor, a second precursor, and a third precursor into the reaction chamber to radially flow the first precursor, the second precursor, and the third precursor upon the heated substrate; and
injecting a fourth precursor into the reaction chamber through a plurality of conduits connected to the reaction chamber, the plurality of conduits providing distributed spray paths along which the fourth precursor is passed to the reaction chamber.

12. The method of claim 11, further comprising:
cooling the plurality of conduits and connected solid structures.

13. The method of claim 11, further comprising:
cooling walls of the reaction chamber.

14. The method of claim 11, wherein injecting the first precursor, the second precursor, the third precursor, and the fourth precursor comprises continuously injecting the first precursor, the second precursor, the third precursor, and the fourth precursor to perform metal organic chemical vapor deposition.

15. The method of claim 11, wherein injecting the first precursor, the second precursor, the third precursor, and the fourth precursor comprises injecting the first precursor, the second precursor, the third precursor, and the fourth precursor in a pulse mode, a duty cycle of the pulses being adjustable.

16. The method of claim 15, wherein injecting the first precursor, the second precursor, the third precursor, and the fourth precursor comprises alternately injecting the first precursor, the second precursor, the third precursor, and the fourth precursor to perform atomic layer deposition.

17. The method of claim 11, wherein heating the substrate comprises heating a susceptor upon which the substrate is placed.

18. The method of claim 1 1, further comprising:
rotating the substrate within the reaction chamber.

19. The method of claim 11, further comprising:
heating an additional substrate upon which the semiconductor material is to be deposited by reaction of the gaseous precursors in the reaction chamber.

20. A reactor comprising:
a reaction chamber configured to accommodate a substrate;
at least one concentric central conduit configured for injecting a first precursor into the reaction chamber;
a gas distribution chamber for a second precursor; and
a plurality of conduits connecting the gas distribution chamber to the reaction chamber to provide a plurality of distributed spray paths along which the second precursor is passed to the reaction chamber.
